(19) United States
(12) Patent Application Publication
(10) Pub. No.: US 2025/0070104 A1
(43) Pub. Date: Feb. 27, 2025

(54) POWER ELECTRONIC SYSTEM HAVING A POWER SEMICONDUCTOR MODULE AND A CURRENT SENSOR AND POWER SEMICONDUCTOR MODULE

(71) Applicant: Infineon Technologies AG, Neubiberg (DE)

(72) Inventors: Tomas Reiter, Ottobrunn (DE); Dietmar Spltzer, Volkermarkt (AT); Christoph Koch, Salzkotten (DE)

(21) Appl. No.: 18/814,476

(22) Filed: Aug. 24, 2024

(30) Foreign Application Priority Data
Aug. 25, 2023 (DE) 102023122872.2

(51) Int. Cl. H01L 25/16; H01L 23/051; H01L 23/31; H01L 23/495; H01L 23/52; H01L 25/065; H10N 52/00; H10N 59/00

(52) U.S. Cl. CPC H01L 25/165; H01L 23/051; H01L 23/49524; H01L 23/52; H01L 23/3107; H01L 25/0655; H10N 52/00; H10N 59/00

(57) ABSTRACT

A power semiconductor module of a power electronic system includes: a power electronic substrate; a power semiconductor die arranged on and electrically coupled to a first side of the substrate; a plastic frame arranged at the first side and defining an interior volume of the module; and a load current contact electrically connected to the first side and partially exposed from the frame. The frame includes a recess above a side of the load current contact facing away from the substrate. A driver board arranged above the module includes circuitry configured to drive power circuitry of the module. A current sensor arranged on and electrically coupled to a side of the driver board facing the module is configured to detect an alternating current flowing through the load current contact. The sensor is arranged at least partially within the recess. The frame electrically isolates the sensor from the load current contact.

### TECHNICAL FIELD

This disclosure relates in general to a power electronic system comprising a power semiconductor module and a current sensor as well as to a power semiconductor module configured to be used in a power electronic system.

### BACKGROUND

A power electronic system may comprise one or more power semiconductor modules configured to operate with a high electrical voltage and/or a strong electrical current, as well as a driver board comprising driver circuitry configured to control power circuitry of the power semiconductor module(s). Such a power electronic system may for example constitute (a part of) an electrical circuit like an inverter circuit, a converter circuit, etc. In order for the driver circuitry to properly control (drive) the power circuitry of the power semiconductor module(s), it may be necessary to provide the driver circuitry via dedicated current sensors with measurements of a current flowing into or out of the power semiconductor module(s). However, such current sensors may require a certain amount of space in the power electronic system and/or may increase the fabrication complexity and/or may increase the costs of the power electronic system.

Improved power electronic systems as well as improved power semiconductor modules configured for use in a power electronic system may help in solving these and other problems.

### SUMMARY

Various aspects pertain to a power electronic system, comprising: at least one power semiconductor module, comprising: a power electronic substrate comprising a first side, at least one power semiconductor die arranged on and electrically coupled to the first side of the power electronic substrate, a plastic frame arranged at the first side of the power electronic substrate, the plastic frame defining an interior volume of the power semiconductor module, wherein the power semiconductor die is arranged in the interior volume, and a first load current contact electrically connected to the first side of the power electronic substrate and partially exposed from the plastic frame, the first load current contact comprising a first side facing away from the power electronic substrate and an opposite second side, wherein the plastic frame comprises a recess above the first side of the first load current contact; a driver board arranged above the power semiconductor module, the driver board comprising driver circuitry configured to drive power circuitry of the at least one power semiconductor module; and a current sensor arranged on and electrically coupled to a second side of the driver board facing the at least one power semiconductor module, the current sensor being configured to detect a load current flowing through the first load current contact, wherein the current sensor is arranged at least partially within the recess and wherein the plastic frame is configured to electrically isolate the current sensor from the first load current contact.

Various aspects pertain to a power semiconductor module, comprising: a power electronic substrate comprising a first side, at least one power semiconductor die arranged on and electrically coupled to the first side of the power electronic substrate, a plastic frame arranged at the first side of the power electronic substrate, the plastic frame defining an interior volume of the power semiconductor module, wherein the power semiconductor die is arranged in the interior volume, and a first load current contact electrically connected to the first side of the power electronic substrate and partially exposed from the plastic frame, the first load current contact comprising a first side facing away from the power electronic substrate and an opposite second side, wherein the plastic frame comprises a recess above the first side of the first load current contact configured to accept a current sensor and wherein the plastic frame is configured to electrically isolate a current sensor in the recess from the first load current contact.

Various aspects pertain to a power electronic system, comprising: at least one power semiconductor module, comprising: a power electronic substrate comprising a first side, at least one power semiconductor die arranged on and electrically coupled to the first side of the power electronic substrate, a first spring element mechanically and electrically connected to the first side of the power electronic substrate; a driver board arranged above the power semiconductor module such that a first side of the driver board faces away from the power semiconductor module and an opposite second side faces the power semiconductor module, the driver board comprising driver circuitry configured to drive power circuitry of the at least one power semiconductor module; a first load current contact arranged on the first side of the driver board and electrically coupled to the first spring element; and a current sensor arranged on and electrically coupled to the second side of the driver board, the current sensor being configured to detect a load current flowing through the first load current contact.

### BRIEF DESCRIPTION OF THE DRAWINGS

The accompanying drawings illustrate examples and together with the description serve to explain principles of the disclosure. Other examples and many of the intended advantages of the disclosure will be readily appreciated in view of the following detailed description. The elements of the drawings are not necessarily to scale relative to each other. Identical reference numerals designate corresponding similar parts.

FIG. 1 shows a sectional view of a power electronic system comprising a power semiconductor module, a driver board and a current sensor configured to detect a load current flowing through a first load current contact of the power semiconductor module.

FIG. 2 shows a plan view of a power semiconductor module, wherein a molded body comprises a recess configured to accept a current sensor.

FIG. 3 shows a detail view of a power semiconductor module, wherein the position of a current sensor above a first load current contact is indicated.

FIGS. 4A to 4C show sectional views of a further power electronic system. In FIGS. 4B and 4C the driver board is omitted in order to show the power semiconductor modules of the power electronic system in greater detail.

FIG. 5 shows a sectional view of a further power electronic system, wherein the first load current contact is arranged on the driver board.

FIG. 6 is a flow chart of an exemplary method for fabricating a power semiconductor module.

### DETAILED DESCRIPTION

In the following detailed description, known structures and elements are shown in schematic form in order to facilitate describing one or more aspects of the disclosure. In this regard, directional terminology, such as “top”, “bottom”, “left”, “right”, “upper”, “lower” etc., is used with reference to the orientation of the Figure(s) being described. Because components of the disclosure can be positioned in a number of different orientations, the directional terminology is used for purposes of illustration only. It is to be understood that other examples may be utilized and structural or logical changes may be made.

In addition, while a particular feature or aspect of an example may be disclosed with respect to only one of several implementations, such feature or aspect may be combined with one or more other features or aspects of the other implementations as may be desired and advantageous for any given or particular application, unless specifically noted otherwise or unless technically restricted. Furthermore, to the extent that the terms “include”, “have”, “with” or other variants thereof are used in either the detailed description or the claims, such terms are intended to be inclusive in a manner similar to the term “comprise”. The terms “coupled” and “connected”, along with derivatives thereof may be used. It should be understood that these terms may be used to indicate that two elements cooperate or interact with each other regardless whether they are in direct physical or electrical contact, or they are not in direct contact with each other; intervening elements or layers may be provided between the “bonded”, “attached”, or “connected” elements. However, it is also possible that the “bonded”, “attached”, or “connected” elements are in direct contact with each other. Also, the term “exemplary” is merely meant as an example, rather than the best or optimal.

The examples of a power semiconductor module described below may use various types of semiconductor dies or circuits incorporated in the semiconductor dies, among them AC/DC or DC/DC converter circuits, power MOS transistors, power Schottky diodes, JFETs (Junction Gate Field Effect Transistors), power bipolar transistors, power integrated circuits, etc. The examples may also use semiconductor dies comprising MOS transistor structures or vertical transistor structures like, for example, IGBT (Insulated Gate Bipolar Transistor) structures.

An efficient power electronic system and an efficient power semiconductor module may for example reduce material consumption, ohmic losses, chemical waste, etc. and may thus enable energy and/or resource savings. Improved power electronic systems and improved power semiconductor modules, as specified in this description, may thus at least indirectly contribute to green technology solutions, i.e. climate-friendly solutions providing a mitigation of energy and/or resource use.

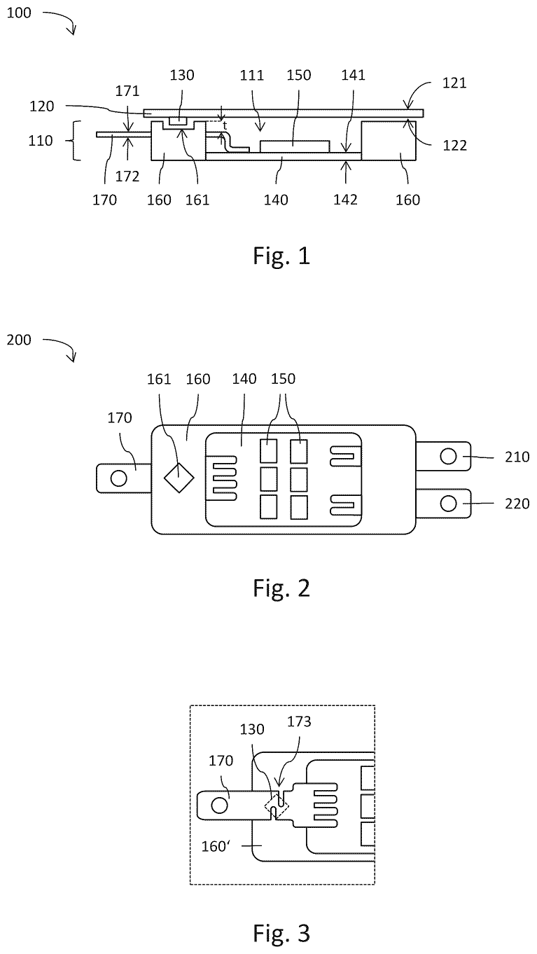

FIG. 1 shows a sectional view of a power electronic system 100 comprising at least a power semiconductor module 110, a driver board 120 and a current sensor 130.

The power electronic system 100 may constitute or be part of any suitable electric circuit. For example, the power electronic system 100 may constitute or be part of a converter circuit, an inverter circuit, a half bridge circuit, a full bridge circuit, etc. According to an example, the power electronic system 100 is configured for use in automotive applications.

In the example shown in FIG. 1, the power electronic system 100 comprises a single power semiconductor module 110. It is however also possible that the power electronic system 100 comprises a plurality of power semiconductor modules 110, for example two, three or more power semiconductor modules 110 that are electrically connected in order to provide e.g. one of the exemplary circuits mentioned above. The more than one power semiconductor modules 110 may for example be arranged side by side and may for example all be connected to the same driver board 120. According to an example, the more than one power semiconductor modules 110 are identical. According to another example, at least one of the power semiconductor modules 110 has an individual architecture.

The at least one power semiconductor module 110 comprises a power electronic substrate 140, at least one power semiconductor die 150, a plastic frame 160 and a first load current contact 170. The current sensor 130 is in particular configured to detect a load current flowing through the first load current contact 170 during operation of the power electronic system 100. The power electronic system 100 may be configured to be coupled to an electric motor, in particular such that the first load current contact 170 is coupled to the electric motor. Depending on the operating mode of the electric motor, the first load current contact 170 may carry an AC current or a DC current. In other words, the load current may be an AC current or a DC current. According to an example, the power semiconductor module 110 may comprise additional components, e.g. further power semiconductor dies, direct current contacts, etc. not shown in FIG. 1.

The power electronic substrate 140 comprises a first side 141 and the power semiconductor die 150 is arranged on and electrically coupled to the first side 141 of the power electronic substrate 140. The power electronic substrate 140 may also comprise a second side 142 opposite the first side 141.

The power electronic substrate 140 may for example be a substrate of the type direct copper bonded (DCB), direct aluminum bonded (DAB), active metal brazed (AMB), insulated metal substrate (IMS), printed circuit board (PCB), etc. The power electronic substrate 110 may be configured to have a comparatively low thermal resistance.

According to an example, the power electronic system 100 also comprises a baseplate, wherein the second side 142 of the at least one power electronic substrate 140 is arranged on the baseplate. Such a baseplate may for example comprise or consist of Al or Cu and may for example be configured to act as a heatspreader and/or a heatsink.

The at least one power semiconductor die 150 may be electrically and mechanically coupled to the power electronic substrate 140, for example via a joint like a solder joint, a sintered joint or a joint comprising conductive glue. For example, the power semiconductor die 150 may comprise a first power terminal, e.g. a drain, source, collector or emitter terminal arranged on a lower side of the power semiconductor die 150, wherein the lower side faces the first side 141 of the power electronic substrate 140 and wherein the first power terminal is connected to the power electronic substrate 140.

The power semiconductor die 150 may for example comprise a second power terminal, e.g. a source, drain, emitter or collector terminal arranged on an upper side of the power semiconductor die 150, opposite the lower side. The power semiconductor die 150 may also comprise a control terminal, e.g. a gate terminal, arranged e.g. on the upper side.

According to an example, the power semiconductor module 110 comprises one or more additional power semiconductor die(s) 150. The more than one power semiconductor dies 150 may all be identical or the more than one power semiconductor dies 150 may be different types of dies. Furthermore, the more than one power semiconductor dies 150 may be electrically connected, for example via the power electronic substrate 140 and/or via electrical connectors like bond wires, ribbons or contact clips.

The plastic frame 160 is arranged at the first side 141 of the power electronic substrate 140. This may mean that the first side 141 is arranged in a first plane and the plastic frame 160 extends at least from the first plane to a certain point above the first plane. The plastic frame 160 defines an interior volume 111 of the power semiconductor module 110, wherein the power semiconductor die 150 is arranged inside the interior volume 111. The power electronic substrate 140 may essentially provide a bottom of the interior volume 111 and the driver board may essentially provide a lid of the interior volume 111.

According to an example, the interior volume 111 is at least partially filled with a suitable dielectric potting material configured to protect the power semiconductor die 150 from environmental influences.

The plastic frame 160 may comprise or consist of any suitable plastic material. The plastic frame 160 may for example comprise or consist of a suitable hard plastic or soft plastic. The plastic frame 160 may essentially surround the power electronic substrate 140 on all lateral sides. The plastic frame 160 may have any suitable dimensions. According to an example, the plastic frame 160 comprises a lower half shell and an upper half shell. In this case, the first load current contact 170 may for example be arranged (i.e. be sandwiched) between the lower and upper half shells.

The first load current contact 170 is electrically connected to the first side 141 of the power electronic substrate 140. Furthermore, the first load current contact 170 is partially exposed from the plastic frame 160. This may mean that the first load current contact 170 comprises an interior portion arranged within the interior volume 111 of the power semiconductor module 110, a middle portion extending through the plastic frame 160 and an exterior portion exposed from the plastic frame 160 at a first lateral side of the power semiconductor module 110.

The first load current contact 170 may comprise or consist of any suitable metal or metal alloy. For example, the first load current contact 170 may comprise or consist of Al or Cu. The first load current contact 170 may for example be a leadframe part.

According to an example, the first load current contact 170 is configured as an output power contact of the power semiconductor module 110. The power semiconductor module 110 may for example also comprise a first and a second direct current contact which may for example be arranged at a second lateral side of the power semiconductor module, opposite the first lateral side. The first and second direct current contacts may e.g. be configured to provide an input power to the power semiconductor module 110.

The first load current contact 170 comprises a first side 171 facing away from the power electronic substrate 140 and an opposite second side 172. The second side 172 of the first load current contact 170 may for example be soldered or sintered or glued with conductive glue to the first side 141 of the power electronic substrate 140.

According to the example shown in FIG. 1, the first load current contact 170 is coupled to the first side 141 of the power electronic substrate 140 in a first plane and the first load current contact 170 is exposed from the plastic frame 160 in a second plane which is arranged above the first plane. The first load current contact 170 may for example comprise a first part which is arranged in the first plane, a second part which is arranged in the second plane and a connecting part connecting the first and second parts. The connecting part may for example be arranged essentially perpendicular with respect to the first and/or the second plane (compare FIG. 1).

A vertical distance between the first and second planes, the vertical distance being measured perpendicular to the first side 141 of the power electronic substrate 140, may for example be in the range of about 5 mm to about 10 mm. The lower limit of this range may also be about 6 mm or about 7 mm and the upper limit may also be about 9 mm or about 8 mm.

According to an example, the current sensor 130 is arranged in a third plane above the second plane. A distance between the second and third planes may for example be one third or one quarter or one fifth or less of a distance between the first and second planes.

The plastic frame 160 comprises a recess 161 above the first side 171 of the first load current contact 170. The current sensor 130 is arranged at least partially within the recess 161. Furthermore, the plastic frame 160 is configured to electrically isolate the current sensor 130 from the first load current contact 170. This may mean that the plastic frame 170 may be thick enough between the current sensor 130 and the first side 171 of the first load current contact 170 that a flashover is prevented.

According to an example, there is a gap in the size of about 0.25 mm to about 0.8 mm between the current sensor 130 and a bottom of the recess 161, the gap being measured perpendicular to the first side 141 of the power electronic substrate 140. The lower limit of this range may also be about 0.3 mm, about 0.4 mm or about 0.5 mm and the upper limit may also be about 0.7 mm or about 0.6 mm. According to an example, the gap is filled with a gas, e.g. air. According to another example, the gap is filled with a filler material like one or more of silicone, a foam, a glue or a polymer. The filler material may be configured to prevent the current sensor 130 from being bumped into the bottom of the recess due to e.g. vibrations, a mechanical shock, etc.

According to an example, above the first side 171 of the first load current contact 170 the plastic frame 160 has a thickness t in the range of about 0.8 mm to about 1.5 mm. The lower limit of this range may also be about 0.9 mm or 1.0 mm and the upper limit may also be about 1.4 mm or 1.3 mm or 1.2 mm or 1.1 mm.

The recess 161 may have any suitable shape and any suitable dimensions. For example, the recess 161 may have an essentially rectangular or quadratic shape as viewed from above the current sensor 130. The bottom of the recess 161 may be essentially flat. The recess 161 may for example have a depth of 3 mm or less, or 2 mm or less, or 1.5 mm or less, or 1 mm or less, or 0.5 mm or less, or 0.3 mm or less, the depth being measured perpendicular to the first side 141 of the power electronic substrate 140. The recess 161 may for example have a length and/or a width of 10 mm or less, or 7 mm or less, or 5 mm or less, or 3 mm or less, or 2 mm or less, the length and width being measured parallel to the first side 141.

The driver board 120 is arranged above the power semiconductor module 110. The driver board 120 comprises driver circuitry configured to drive power circuitry of the at least one power semiconductor module 110 (the power circuitry in particular comprises the at least one power semiconductor die 150). The driver board 120 may comprise a first side 121 facing away from the power semiconductor module 110 and an opposite second side 122. The current sensor 130 is arranged on and electrically coupled to the second side 122 of the driver board 120.

The current sensor 130 may for example be a surface mounted device (SMD) which may for example comprise a sensor die arranged on a die carrier and a plastic body encapsulating the sensor die. The current sensor 130 may for example comprise a differential Hall sensor element. The current sensor 130 may for example be coupled to the driver board 120 via a solder joint. The current sensor 130 may be configured to provide the driver circuitry with measurement data of the load current flowing through the first load current contact 170.

FIG. 2 shows a plan view of the power semiconductor module 200 which may be similar or identical to the power semiconductor module 110, except for the differences described in the following. The power semiconductor module 200 may be used in the power electronic system 100 in place of the power semiconductor module 110.

As shown in FIG. 2, the power semiconductor module 200 comprises a plurality of power semiconductor dies 150 coupled to the power electronic substrate 140 to provide the power circuitry of the power semiconductor module 200. The power semiconductor module 200 further comprises a first direct current contact 210 and a second direct current contact 220. The first and second direct current contacts 210, 220 may comprise or consist of the same metal or metal alloy as the first load current contact 170. In particular, the first load current contact 170 and the first and second direct current contacts 210, 220 may be parts of the same leadframe.

FIG. 3 shows a detail view the power semiconductor module 200, wherein the detail view in particular shows the first load current contact 170. Furthermore, the plastic frame 160 of the power semiconductor module 200 may comprise an upper and a lower half shelf, wherein the upper half shelf is omitted in FIG. 3 and only the lower half shelf 160′ is shown.

As shown in FIG. 3, the first load current contact 170 may comprise a narrowing 173 configured to increase a current density of the load current flowing through the first load current contact 170. The narrowing 173 may be arranged vertically below the position of the current sensor 130 (the position of the current sensor 130 is indicated with dashed lines in FIG. 3). In this manner, the measurement accuracy of the current sensor 130 may be improved.

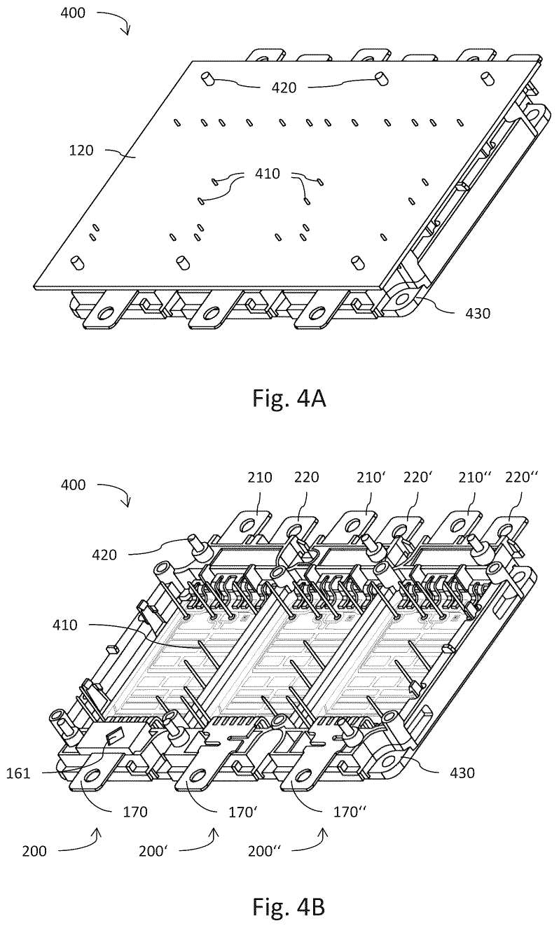

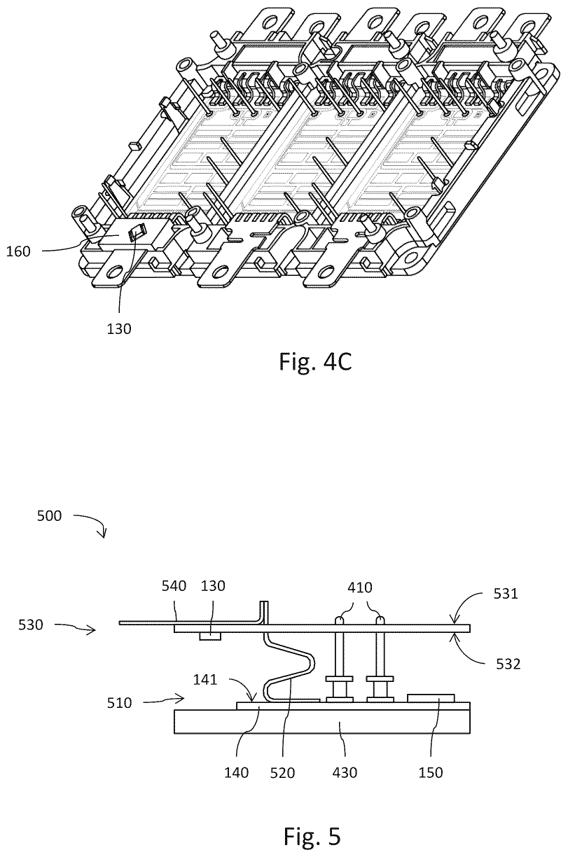

FIG. 4A shows a perspective view of a further power electronic system 400 which may be similar or identical to the power electronic system 100, except for the differences described in the following. FIG. 4B shows a perspective view of the power electronic system 400, wherein the driver board 120 is omitted in order to show the power semiconductor modules 200 of the power electronic system 400.

The power electronic system 400 may for example comprise three power semiconductor modules 200, 200′ and 200″ which may for example be arranged side by side and which may all be connected to the driver board 120. The power electronic system 400 may for example be configured to provide three-phase current.

An electrical connection between the driver board 120 and the power semiconductor modules 200, 200′ and 200″ may comprise electrical connectors like, for example, pins 410. The pins 410 may for example be pressfit pins. A mechanical connection between the driver board 120 and the power semiconductor modules 200, 200′ and 200″ may for example comprise mechanical connectors 420 like, for example, hollow heat stakes. Mechanical connector 420 in the form of hollow heat stakes may for example help in properly aligning the driver board 120 relative to the power semiconductor modules 200, 200′ and 200″.

According to an example, the power electronic system 400 may also comprise a baseplate 430, wherein the power semiconductor modules 200, 200′ and 200″ are arranged on the baseplate 430. The baseplate 430 may for example be configured as a heatspreader and/or as (part of) a heatsink.

In the example shown in FIG. 4B, only the leftmost of the power semiconductor modules 200 comprises a recess 161 configured to accept a current sensor 130. However, it is also possible that one or both of the other power semiconductor modules 200′, 200″ also comprise a recess 161. In other words, the power electronic system 400 may comprise two or even three current sensors 130, wherein a first one of the current sensors 130 is arranged at the first load current contact 170, a second one of the current sensors 130 is arranged at a second load current contact 170′ and/or a third one of the current sensors 130 is arranged at a third load current contact 170″.

As shown in FIG. 4B, the plastic frame 160 may surround a middle portion of the first load current contact 170 on all sides. This may mean that the middle portion of the first load current contact 170 is electrically isolated at the sides covered by the plastic frame 160.

FIG. 4C shows the current sensor 130 arranged (partially) in the recess 161 of the plastic frame 160.

FIG. 5 shows a sectional view of a further power electronic system 500 which may be similar or identical to the power electronic system 100 or 400, except for the differences described in the following.

The power electronic system 500 comprises at least one power semiconductor module 510. The power semiconductor module 510 may be similar or identical to the power semiconductor module 110 or 200, except that a plastic frame of the power semiconductor module 510 does not necessarily comprise the recess 161.

The power semiconductor module 510 comprises the power electronic substrate 140, the at least one power semiconductor die 150 arranged on and electrically coupled to the first side 141 of the power electronic substrate 140 and a first spring element 520. The first spring element 520 is mechanically and electrically connected to the first side 141 of the power electronic substrate 140.

The power electronic system also comprises a driver board 530 arranged above the power semiconductor module 510. The driver board 530 may be similar or identical to the driver board 120, except for the differences described in the following.

A first side 531 of the driver board 530 faces away from the power semiconductor module 510 and an opposite second side 532 faces the power semiconductor module 510. The driver board 530 comprises driver circuitry configured to drive power circuitry of the at least one power semiconductor module 510.

A first load current contact 540 is arranged on the first side 531 of the driver board 530 and is electrically coupled to the first spring element 520. For example, the first load current contact 540 and the spring element may be coupled via a solder joint or a welded joint. The first load current contact 540 may essentially be similar or identical to the first load current contact 170, except for being arranged on the driver board 530.

The current sensor is 130 arranged on and electrically coupled to the second side 553 of the driver board 530. Furthermore, the current sensor 130 is configured to detect a load current flowing through the first load current contact 540.

According to an example, the driver board 530 comprises an opening and the first spring element 520 extends through the opening in the driver board 530 to the first side 531 of the driver board 530.

According to an example, the driver circuitry of the driver board 530 and the power circuitry of the power semiconductor module 510 are connected via one or more pins 410, e.g. pressfit pins. According to an example, the power electronic system 500 also comprises the baseplate 430. The power electronic system 500 may also comprise first and second direct current contacts which may for example also be arranged on the first side 531 of the driver board 530 or which may be arranged on the power electronic substrate 140. In the case that the direct current contacts are arranged on the driver board 530, the direct current contacts may e.g. be coupled to further spring elements of the power electronic system 500.

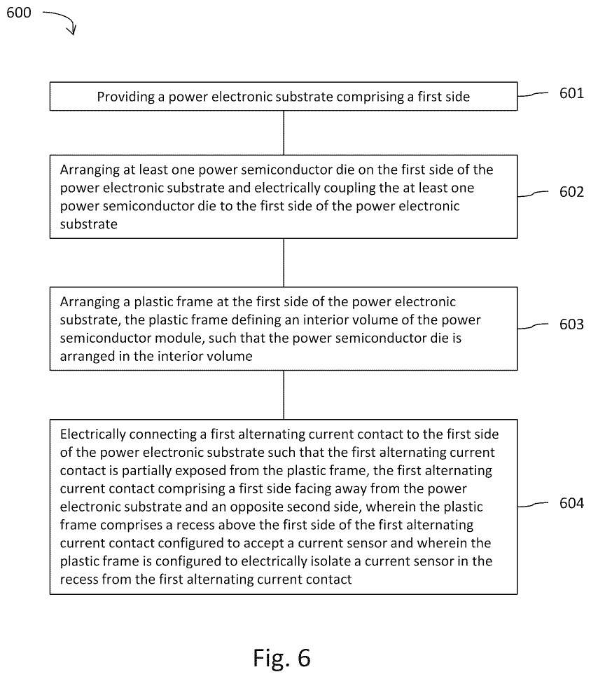

FIG. 6 is a flow chart of a method 600 for fabricating a power semiconductor module. The method 600 may for example be used to fabricate the power semiconductor modules 110, 200 and 510.

The method 600 comprises at 601 a process of providing a power electronic substrate comprising a first side, at 602 a process of arranging at least one power semiconductor die on the first side of the power electronic substrate and electrically coupling the at least one power semiconductor die to the first side of the power electronic substrate, at 603 a process of arranging a plastic frame at the first side of the power electronic substrate, the plastic frame defining an interior volume of the power semiconductor module, such that the power semiconductor die is arranged in the interior volume, and at 604 a process of electrically connecting a first load current contact to the first side of the power electronic substrate such that the first load current contact is partially exposed from the plastic frame, the first load current contact comprising a first side facing away from the power electronic substrate and an opposite second side, wherein the plastic frame comprises a recess above the first side of the first load current contact configured to accept a current sensor and wherein the plastic frame is configured to electrically isolate a current sensor in the recess from the first load current contact.

In the following, the power electronic system and the power semiconductor module are further explained using specific examples.

Example 1 is a power electronic system, comprising: at least one power semiconductor module, comprising: a power electronic substrate comprising a first side, at least one power semiconductor die arranged on and electrically coupled to the first side of the power electronic substrate, a plastic frame arranged at the first side of the power electronic substrate, the plastic frame defining an interior volume of the power semiconductor module, wherein the power semiconductor die is arranged in the interior volume, and a first load current contact electrically connected to the first side of the power electronic substrate and partially exposed from the plastic frame, the first load current contact comprising a first side facing away from the power electronic substrate and an opposite second side, wherein the plastic frame comprises a recess above the first side of the first load current contact; a driver board arranged above the power semiconductor module, the driver board comprising driver circuitry configured to drive power circuitry of the at least one power semiconductor module; and a current sensor arranged on and electrically coupled to a second side of the driver board facing the at least one power semiconductor module, the current sensor being configured to detect a load current flowing through the first load current contact, wherein the current sensor is arranged at least partially within the recess and wherein the plastic frame is configured to electrically isolate the current sensor from the first load current contact.

Example 2 is the power electronic system of example 1, wherein the current sensor is a surface mounted device.

Example 3 is the power electronic system of example 1 or 2, wherein there is a gap in the range of 0.25 mm to 0.8 mm between the current sensor and a bottom of the recess, the gap being measured perpendicular to the first side of the power electronic substrate.

Example 4 is the power electronic system of example 3, wherein the gap is filled with one or more of silicone, a foam, a glue or a polymer.

Example 5 is the power electronic system of one of the preceding examples, wherein above the first side of the first load current contact the plastic frame has a thickness in the range of 0.8 mm to 1.5 mm.

Example 6 is the power electronic system of one of the preceding examples, wherein the first load current contact is coupled to the first side of the power electronic substrate in a first plane, wherein the first load current contact is exposed from the plastic frame in a second plane, and wherein a vertical distance between the first and second planes is in the range of 5 mm to 10 mm, in particular wherein the vertical distance is 8 mm, the vertical distance being measured perpendicular to the first side of the power electronic substrate.

Example 7 is the power electronic system of one of examples 1 to 5, wherein the first load current contact is coupled to the first side of the power electronic substrate in a first plane, wherein the first load current contact is exposed from the plastic frame in a second plane, wherein the current sensor is arranged in a third plane, and wherein a distance between the second and third planes is one third or less of a distance between the first and second planes.

Example 8 is the power electronic system of one of the preceding examples, wherein the first load current contact comprises a narrowing below the current sensor, the narrowing being configured to increase a current density of the load current.

Example 9 is the power electronic system of one of the preceding examples, wherein the current sensor comprises a differential Hall sensor element.

Example 10 is the power electronic system of one of the preceding examples, wherein the plastic frame comprises a lower half shell and an upper half shell, wherein the first load current contact is arranged between the lower and upper half shells, and wherein the recess is arranged in the upper half shell.

Example 11 is a power semiconductor module, comprising: a power electronic substrate comprising a first side, at least one power semiconductor die arranged on and electrically coupled to the first side of the power electronic substrate, a plastic frame arranged at the first side of the power electronic substrate, the plastic frame defining an interior volume of the power semiconductor module, wherein the power semiconductor die is arranged in the interior volume, and a first load current contact electrically connected to the first side of the power electronic substrate and partially exposed from the plastic frame, the first load current contact comprising a first side facing away from the power electronic substrate and an opposite second side, wherein the plastic frame comprises a recess above the first side of the first load current contact configured to accept a current sensor and wherein the plastic frame is configured to electrically isolate a current sensor in the recess from the first load current contact.

Example 12 is the power semiconductor module of example 11, wherein the first load current contact is a leadframe part, and wherein the plastic frame surrounds a middle portion of the first load current contact on all sides.

Example 13 is the power semiconductor module of example 11 or 12, wherein the plastic frame comprises a lower half shell and an upper half shell, wherein the first load current contact is arranged between the lower and upper half shells, and wherein the recess is arranged in the upper half shell.

Example 14 is a power electronic system, comprising: at least one power semiconductor module, comprising: a power electronic substrate comprising a first side, at least one power semiconductor die arranged on and electrically coupled to the first side of the power electronic substrate, a first spring element mechanically and electrically connected to the first side of the power electronic substrate; a driver board arranged above the power semiconductor module such that a first side of the driver board faces away from the power semiconductor module and an opposite second side faces the power semiconductor module, the driver board comprising driver circuitry configured to drive power circuitry of the at least one power semiconductor module; a first load current contact arranged on the first side of the driver board and electrically coupled to the first spring element; and a current sensor arranged on and electrically coupled to the second side of the driver board, the current sensor being configured to detect a load current flowing through the first load current contact.

Example 15 is the power electronic system of example 14, wherein the first spring element extends through an opening in the driver board to the first side of the driver board.

Example 16 is the power electronic system of example 14 or 15, wherein the current sensor is a surface mounted device.

While the disclosure has been illustrated and described with respect to one or more implementations, alterations and/or modifications may be made to the illustrated examples without departing from the spirit and scope of the appended claims. In particular regard to the various functions performed by the above described components or structures (assemblies, devices, circuits, systems, etc.), the terms (including a reference to a “means”) used to describe such components are intended to correspond, unless otherwise indicated, to any component or structure which performs the specified function of the described component (e.g., that is functionally equivalent), even though not structurally equivalent to the disclosed structure which performs the function in the herein illustrated exemplary implementations of the disclosure.

What is claimed is:

1. A power electronic system, comprising:
at least one power semiconductor module, comprising:
a power electronic substrate;
at least one power semiconductor die arranged on and electrically coupled to a first side of the power electronic substrate;
a plastic frame arranged at the first side of the power electronic substrate, the plastic frame defining an interior volume of the power semiconductor module, wherein the at least one power semiconductor die is arranged in the interior volume; and
a first load current contact electrically connected to the first side of the power electronic substrate and partially exposed from the plastic frame, the first load current contact comprising a first side facing away from the power electronic substrate and an opposite second side,
wherein the plastic frame comprises a recess above the first side of the first load current contact;
a driver board arranged above the power semiconductor module, the driver board comprising driver circuitry configured to drive power circuitry of the at least one power semiconductor module; and
a current sensor arranged on and electrically coupled to a second side of the driver board facing the at least one power semiconductor module, the current sensor being configured to detect a load current flowing through the first load current contact,
wherein the current sensor is arranged at least partially within the recess,
wherein the plastic frame is configured to electrically isolate the current sensor from the first load current contact.

2. The power electronic system of claim 1, wherein the current sensor is a surface mounted device.

3. The power electronic system of claim 1, wherein a gap in a range of 0.25 mm to 0.8 mm is between the current sensor and a bottom of the recess, the gap being measured perpendicular to the first side of the power electronic substrate.

4. The power electronic system of claim 3, wherein the gap is filled with one or more of silicone, a foam, a glue, and a polymer.

5. The power electronic system of claim 1, wherein above the first side of the first load current contact, the plastic frame has a thickness in a range of 0.8 mm to 1.5 mm.

6. The power electronic system of claim 1, wherein the first load current contact is coupled to the first side of the power electronic substrate in a first plane, wherein the first load current contact is exposed from the plastic frame in a second plane, and wherein a vertical distance between the first and second planes is in a range of 5 mm to 10 mm.

7. The power electronic system of claim 6, wherein the vertical distance is 8 mm measured perpendicular to the first side of the power electronic substrate.

8. The power electronic system of claim 1, wherein the first load current contact is coupled to the first side of the power electronic substrate in a first plane, wherein the first load current contact is exposed from the plastic frame in a second plane, wherein the current sensor is arranged in a third plane, and wherein a distance between the second and third planes is one third or less of a distance between the first and second planes.

9. The power electronic system of claim 1, wherein the first load current contact comprises a narrowing below the current sensor, the narrowing being configured to increase a current density of the alternating current.

10. The power electronic system of claim 1, wherein the current sensor comprises a differential Hall sensor element.

11. The power electronic system of claim 1, wherein the plastic frame comprises a lower half shell and an upper half shell, wherein the first load current contact is arranged between the lower and upper half shells, and wherein the recess is arranged in the upper half shell.

12. A power semiconductor module, comprising:
a power electronic substrate;
at least one power semiconductor die arranged on and electrically coupled to a first side of the power electronic substrate;
a plastic frame arranged at the first side of the power electronic substrate, the plastic frame defining an interior volume of the power semiconductor module, wherein the at least one power semiconductor die is arranged in the interior volume; and
a first load current contact electrically connected to the first side of the power electronic substrate and partially exposed from the plastic frame, the first load current contact comprising a first side facing away from the power electronic substrate and an opposite second side,
wherein the plastic frame comprises a recess above the first side of the first load current contact configured to accept a current sensor,
wherein the plastic frame is configured to electrically isolate a current sensor in the recess from the first load current contact.

13. The power semiconductor module of claim 12, wherein the first load current contact is a leadframe part, and wherein the plastic frame surrounds a middle portion of the first load current contact on all sides.

14. The power semiconductor module of claim 12, wherein the plastic frame comprises a lower half shell and an upper half shell, wherein the first load current contact is arranged between the lower and upper half shells, and wherein the recess is arranged in the upper half shell.

15. A power electronic system, comprising:
at least one power semiconductor module, comprising:
a power electronic substrate;
at least one power semiconductor die arranged on and electrically coupled to a first side of the power electronic substrate;
a first spring element mechanically and electrically connected to the first side of the power electronic substrate;
a driver board arranged above the power semiconductor module such that a first side of the driver board faces away from the power semiconductor module and an opposite second side faces the power semiconductor module, the driver board comprising driver circuitry configured to drive power circuitry of the at least one power semiconductor module;
a first load current contact arranged on the first side of the driver board and electrically coupled to the first spring element; and
a current sensor arranged on and electrically coupled to the second side of the driver board, the current sensor being configured to detect a load current flowing through the first load current contact.

16. The power electronic system of claim 15, wherein the first spring element extends through an opening in the driver board to the first side of the driver board.

17. The power electronic system of claim 15, wherein the current sensor is a surface mounted device.
